(19) United States
(12) Patent Application Publication
(10) Pub. No.: US 2025/0343053 A1
(43) Pub. Date: Nov. 6, 2025

(54) DISPERSION PLATE, GAS FEED MECHANISM, AND SUBSTRATE PROCESSING DEVICE

(71) Applicant: Tokyo Electron Limited, Tokyo (JP)

(72) Inventor: Takaaki Kato, Yamanashi (JP)

(21) Appl. No.: 19/267,329

(22) Filed: Jul. 11, 2025

Related U.S. Application Data
(63) Continuation of application No. PCT/JP2024/000536, filed on Jan. 12, 2024.

(30) Foreign Application Priority Data
Jan. 26, 2023 (JP) 2023-010473

(51) Int. Cl. H01L 21/67; H01J 37/32

(52) U.S. Cl. CPC H01L 21/67017; H01J 37/3244

(57) ABSTRACT

Provided is a dispersion plate located in a processing chamber of a substrate processing apparatus, comprising: a disc-shaped main body having a central portion and an outer peripheral portion surrounding the central portion; and a plurality of first holes formed in the central portion and opened into a first space in the processing chamber for processing a substrate, wherein the main body has at the central portion slits penetrating through the main body in a thickness direction.

### CROSS-REFERENCE TO RELATED APPLICATIONS

This application is a bypass continuation application of International Application No. PCT/JP2024/000536 having an international filing date of Jan. 12, 2024 and designating the United States, the International Application being based upon and claiming the benefit of priority from Japanese Patent Application No. 2023-010473 filed on Jan. 26, 2023, the entire contents of which are incorporated herein by reference.

### TECHNICAL FIELD

The present disclosure relates to a dispersion plate, a gas supply mechanism, and a substrate processing apparatus.

### BACKGROUND

For example, Japanese Laid-open Patent Publication No. 2019-203155 proposes a case in which a plate member having a plurality of through-holes for trapping ions in plasma is located directly below a shower plate.

### SUMMARY

The present disclosure provides a dispersion plate capable of reducing thermal stress, a gas supply mechanism, and a substrate processing apparatus.

In accordance with an aspect of the subject application, there is provided a dispersion plate located in a processing chamber of a substrate processing apparatus, comprising: a disc-shaped main body having a central portion and an outer peripheral portion surrounding the central portion; and a plurality of first holes formed in the central portion and opened into a first space in the processing chamber for processing a substrate, wherein the main body has at the central portion slits penetrating through the main body in a thickness direction.

### BRIEF DESCRIPTION OF THE DRAWINGS

FIG. 1 is a cross-sectional perspective view showing an example of a plasma processing apparatus according to one embodiment.

FIG. 2 is a cross-sectional view showing a shower head of the plasma processing apparatus of FIG. 1 and its neighboring parts.

FIG. 3 is an A-A cross-sectional view of FIG. 2 showing a slit of a first embodiment.

FIG. 4 is a diagram showing an example of a simulation result of thermal stress applied to a dispersion plate without a slit.

FIG. 5 is an A-A cross-sectional view of FIG. 2 showing slits of a second embodiment.

FIG. 6 is an A-A cross-sectional view of FIG. 2 showing slits of a third embodiment.

FIG. 7 is an A-A cross-sectional view of FIG. 2 showing slits of a fourth embodiment.

FIG. 8 is an A-A cross-sectional view of FIG. 2 showing slits of a fifth embodiment.

### DETAILED DESCRIPTION

Hereinafter, embodiments of the present disclosure will be described with reference to the accompanying drawings. In each drawing, like reference numerals will be used for like parts, and redundant description thereof may be omitted.

In this specification, directions such as parallel, right-angled, orthogonal, horizontal, vertical, up and down, and left and right are allowed to deviate without spoiling the effect of the embodiment. The shape of a corner is not limited to a right angle and may be rounded in an arch shape. The terms parallel, right-angled, orthogonal, horizontal, vertical, circular, and equal may include substantially parallel, substantially right-angled, substantially orthogonal, substantially horizontal, substantially vertical, substantially circular, and substantially equal, respectively.

### (Substrate Processing Apparatus)

Substrate processing includes film formation using an atomic layer deposition (ALD) apparatus and a chemical vapor deposition (CVD) apparatus, and etching using an atomic layer etching (ALE) apparatus. In the case of performing film formation and/or etching using plasma generated by very high frequency (VHF) or ultra high frequency (UHF) electromagnetic waves (high frequency), damage from ions is reduced compared to the case of using plasma generated by high frequency of 13.56 MHZ, for example. In addition, high-density plasma can be expected to increase a deposition speed (film formation speed) and an etching speed, and provide a high coverage.

In an ALD apparatus or an ALE apparatus, gases are repeatedly switched in a short period of time. Therefore, it is important to reduce the processing space in order to realize high-speed gas switching.

The substrate processing apparatus according to the present embodiment includes a dispersion plate that is provided between a processing space for a substrate and a plasma space and defines these spaces. The height of the processing space and the plasma space is several millimeters (for example, 2 mm) to several tens of millimeters, which is very small, in order to improve gas replacement efficiency. Therefore, the dispersion plate is susceptible to heat input from the plasma generated in the plasma space and heat from a heater embedded in a substrate placing table. A plurality of holes are formed at the center of the dispersion plate, so that the solid cross-sectional area that contributes to the horizontal heat conduction of the dispersion plate is reduced. Hence, the temperature is more likely to increase at the central portion of the dispersion plate than at the outer peripheral portion thereof. As a result, thermal stress that exceeds a strength of an aluminum alloy, which decreases as the temperature increases, may be generated at the dispersion plate. If thermal stress that exceeds the strength of the dispersion plate occurs, the dispersion plate may undergo plastic deformation. In order to control the plasma uniformly, it is important to keep the dimensions of the plasma space uniform. However, a plastically deformed dispersion plate does not return to its original state, and the dimensions of the plasma space and the processing space change, which may reduce the plasma generation efficiency and impair the uniformity of the plasma control on the substrate. Therefore, in the embodiment to be described below, a substrate processing apparatus including a dispersion plate capable of reducing thermal stress is proposed.

### (Plasma Processing Apparatus)

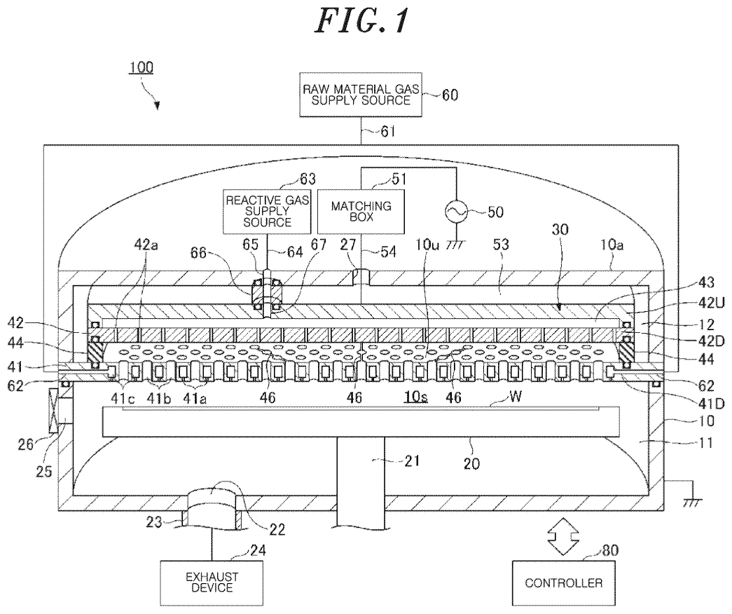

Hereinafter, the configuration of a plasma processing apparatus 100 according to an embodiment will be described with reference to FIG. 1. FIG. 1 is a schematic cross-sectional view showing an example of the plasma processing apparatus 100 according to an embodiment.

The plasma processing apparatus 100 includes a processing chamber 10, a placing table 20 located in the processing chamber 10, a shower head 30 located above the placing table 20, and a controller 80. The plasma processing apparatus 100 is an example of a substrate processing apparatus according to an embodiment.

The processing chamber 10 defines an inner space of the plasma processing apparatus 100. A substrate W, such as a semiconductor wafer, is processed in the inner space of the processing chamber 10. The processing chamber 10 has a substantially cylindrical shape, and the shower head 30 is located at the inner upper portion of the processing chamber 10. The processing chamber 10 is made of a metal such as aluminum or the like. The processing chamber 10 is grounded.

The sidewall of the processing chamber 10 provides a passage 25. The substrate W passes through the passage 25 when it is transferred between the inside of the processing chamber 10 and the outside of the processing chamber 10. The passage 25 can be opened and closed by a gate valve 26. The gate valve 26 is provided along the sidewall of the processing chamber 10.

The bottom portion of the processing chamber 10 provides an exhaust port 22. The exhaust port 22 is connected to an exhaust device 24 via an exhaust line 23. The exhaust device 24 includes a pressure controller having an automatic pressure control valve (not shown) and a vacuum pump such as a turbo molecular pump or the like. A gas in the processing chamber 10 can be exhausted to the outside by the exhaust device 24 via the exhaust port 22. The processing of the substrate W is performed by controlling the inner atmosphere of the processing chamber 10 to a vacuum atmosphere.

The placing table 20 places the substrate W thereon. The substrate W is placed on the placing table 20 in a substantially horizontal state. The placing table 20 may be supported by a support member 21. The support member 21 extends upward from the bottom portion of the processing chamber 10. The placing table 20 and the support member 21 may be made of a dielectric material such as aluminum nitride or the like.

The shower head 30 has an upper electrode 42 and a dispersion plate 41. The upper electrode 42 and the dispersion plate 41 are provided above the placing table 20 to face each other. The upper electrode 42 and the dispersion plate 41 are made of a metal such as an aluminum alloy, nickel, a nickel alloy, stainless steel, or the like.

The upper electrode 42 includes a disc-shaped upper shower plate 42D, and a disc-shaped support plate 42U with a concave surface on a plasma space 10u side. The dispersion plate 41 is provided below the upper electrode 42 in the processing chamber 10. The upper shower plate 42D and the dispersion plate 41 are perforated plates, and have a shower plate structure that supplies a gas from a plurality of holes. The shower head 30 is an example of a gas supply mechanism having the dispersion plate 41.

The plasma space 10u is formed below the support plate 42U with the upper shower plate 42D interposed therebetween. The space defined by the support plate 42U and the upper shower plate 42D functions as a gas diffusion space 43.

The bottom surface of the upper shower plate 42D may have a convex shape or the like. In addition, a dielectric may be formed as a thin plate directly below the upper shower plate 42D, and may be deformed (bent) by an external force to change the gap between the upper shower plate 42D and the metal surface, thereby controlling the plasma.

A VHF-band high-frequency (electromagnetic) power from a high-frequency power supply 50 is supplied to the upper electrode 42 via a matching box 51 and a power transmission line 54. The VHF-band high-frequency power is also referred to as “VHF power.” The dispersion plate 41 has a lower shower plate 41D. On the opposite side of the lower shower plate 41D to the plasma space 10u, a processing space 10s is formed between the lower shower plate 41D and the placing table 20. The VHF power is supplied to the plasma space 10u between the upper electrode 42 and the dispersion plate 41, and a gas to be described later is supplied thereto. The plasma processing apparatus 100 is a remote-type plasma processing apparatus in which plasma is produced from a gas in the plasma space 10u and active species such as radicals and ions in the plasma are supplied from the plasma space 10u to the processing space 10s.

The power transmission line 54 is connected to the upper electrode 42 through a through-hole 27 formed in a ceiling wall 10a of the processing chamber 10. In the present embodiment, the high-frequency power supplied from the high-frequency power supply 50 has a VHF frequency, which is 30 MHz to 300 MHz. However, the frequency of the high-frequency power supplied from the high-frequency power supply 50 is not limited thereto, and may be, e.g., a UHF frequency or a radio frequency (RF) of 13 MHz or higher. The UHF range is 300 MHz to 3 GHz.

The lower shower plate 41D faces the upper shower plate 42D below the upper shower plate 42D. The diameter of the lower shower plate 41D is greater than that of the upper shower plate 42D, and is equal to the diameter of the processing chamber 10. The outer periphery of the lower shower plate 41D is sandwiched and fixed between the upper part and lower part of the processing chamber 10 by the sidewall of the processing chamber 10. As a result, the lower shower plate 41D divides the inner space of the processing chamber 10 into an upper space 12 in which the shower head 30 is provided and a lower space 11 in which the placing table 20 is provided.

A waveguide 53 is formed between the ceiling wall 10a and the support plate 42U along the upper surface and outer periphery of the support plate 42U. The waveguide 53 extends vertically between the sidewall of the processing chamber 10 and the support plate 42U, and extends to the outer peripheral upper surface of the lower shower plate 41D. An annular dielectric radiation part 44 is located between the upper shower plate 42D and the lower shower plate 41D. The diameter of the outer peripheral surface of the radiation part 44 is equal to the diameter of the upper shower plate 42D. The radiation part 44 transmits the VHF power propagated through the waveguide 53 and radiates it into the plasma space 10u.

The upper shower plate 42D is provided with a plurality of through-holes 42a that penetrate through the upper electrode 42 vertically. A reactive gas is supplied from a reactive gas supply source 63 through the gas supply line 64, and is supplied to the gas diffusion space 43 of the support plate 42U through the through-hole 65 that penetrates through the ceiling wall 10a, the annular member 66 that connects the ceiling wall 10a and the support plate 42U, and the through-hole 67 that penetrates through the support plate 42U. The reactive gas is discharged into the plasma space 10u from the plurality of through-holes 42a of the upper shower plate 42D that communicate with the gas diffusion space 43.

The dispersion plate 41 has the disc-shaped lower shower plate 41D with a thickness of, for example, about 12 mm. The lower shower plate 41D is an example of a disc-shaped main body. Further, the dispersion plate 41 has a plurality of gas holes 41b (through-holes) that penetrate through the lower shower plate 41D vertically and are opened to the processing space 10s. The processing space 10s is an example of a first space in which the substrate W in the processing chamber 10 is processed. The gas supplied to the plasma space 10u and excited by the plasma, and the active species of radicals and ions in the plasma are supplied from the plurality of gas holes 41b to the processing space 10s, and are used for the substrate processing.

### (Slits of First Embodiment)

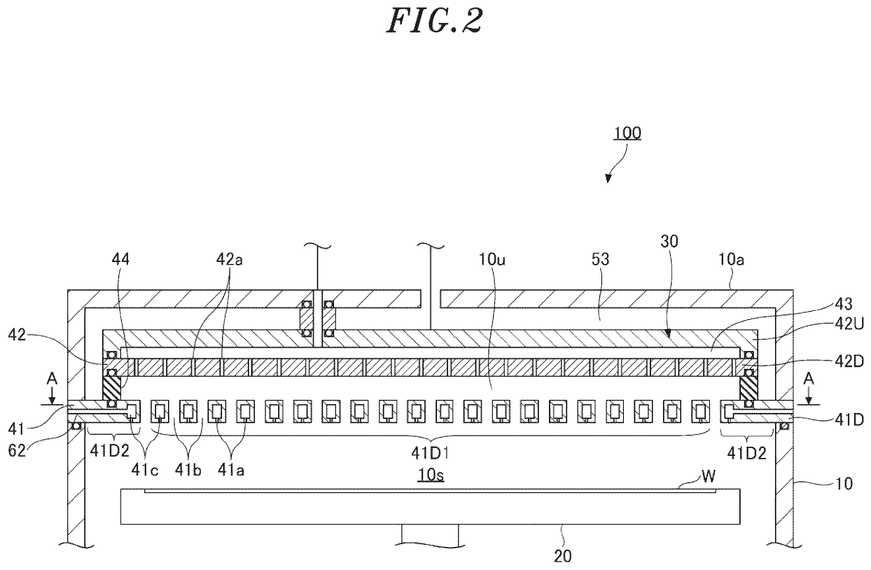

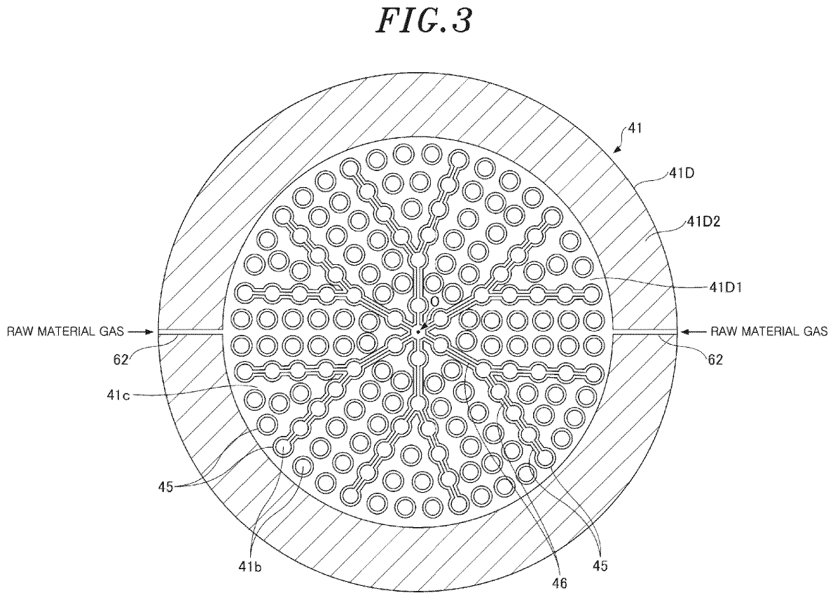

The description will be continued with reference to FIGS. 2 and 3 in addition to FIG. 1. FIG. 2 is a cross-sectional view showing the shower head 30 of the plasma processing apparatus 100 in FIG. 1 and its neighboring parts. FIG. 3 is an example of an A-A cross-sectional view of FIG. 2, showing slits 46 of the first example.

As shown in FIGS. 1 to 3, gas supply ports 62 that communicate with channels (diffusion paths) 41c are formed at two locations on the outer periphery of the lower shower plate 41D. A central portion 41D1 of the lower shower plate 41D is an area surrounded by an outer peripheral portion 41D2 of the lower shower plate 41D. In the area of the central portion 41D1, a plurality of gas holes 41b and slits 46 penetrate through the lower shower plate 41D, and the space other than the plurality of gas holes 41b and slits 46 serves as the channels 41c through which a raw material gas flows through a partition wall 45. In other words, the plurality of gas holes 41b and slits 46 are partitioned from the channels 41c by the partition wall 45. The partition wall 45 may be made of, for example, an aluminum alloy. As shown in FIG. 1, the raw material gas from a raw material gas supply source 60 is branched into two paths through a gas supply line 61, and is supplied into the channels 41c from the gas supply ports 62.

As shown in FIGS. 1 and 2, the lower shower plate 41D is provided with a plurality of gas holes 41a. The plurality of gas holes 41a are provided under the channels 41c of the dispersion plate 41, and are opened downward toward the processing space 10s. In other words, the gas holes 41a are opened on the surface of the lower shower plate 41D that faces the placing table 20. The raw material gas flows through the channels 41c in the lower shower plate 41D and is supplied to the processing space 10s from the gas holes 41a.

In the case of performing film formation using the ALD method, first, the raw material gas is supplied to the processing space 10s from the plurality of gas holes 41a of the lower shower plate 41D. In this case, the VHF power is not supplied. As a result, the raw material gas is chemically adsorbed on the surface of the substrate W.

After the raw material gas is adsorbed on the substrate W, an inert gas (purge gas) such as N₂ gas is supplied from the reactive gas supply source 63 into the processing chamber 10 to replace the raw material gas in the processing chamber 10 with the inert gas, for example. Next, the reactive gas is supplied to the plasma space 10u from the plurality of through-holes 42a of the upper shower plate 42D. In this case, the VHF power is supplied from the radiation part 44 to the plasma space 10u, and the reactive gas is turned into plasma in the plasma space 10u. The reactive gas excited by the plasma and the active species of radicals and ions in the plasma are introduced into the processing space 10s through the plurality of gas holes 41b. Accordingly, the raw material gas adsorbed on the substrate W reacts with the reactive gas. When the raw material gas is a silicon-containing gas and the reactive gas is NHs gas or N₂ gas, the silicon-containing gas on the surface of the substrate W is nitrided by NHx radicals generated by decomposition of NH₃ molecules, and a silicon nitride film is formed on the substrate W.

The plurality of gas holes 41b are an example of a plurality of first holes that supply a first gas (reactive gas) to the first space (the processing space 10s). The first gas may include a plasma excitation gas in addition to the reactive gas. The plasma excitation gas may be an inert gas such as Ar gas or the like.

The channel 41c in the lower shower plate 41D is a diffusion path formed in the central portion 41D1, and is an example of a diffusion path for diffusing a second gas (raw material gas) different from the first gas. Further, the plurality of gas holes 41a are an example of a plurality of second holes through which a second gas from the channels 41c flows toward the first space (the processing space 10s). The second gas includes a silicon-containing gas as a raw material gas. The silicon-containing gas may be silane (SiH₄) gas, dichlorosilane (SiH2Cl₂:DCS) gas, or trisilylamine (Si₃H₉N:TSA) gas. The second gas may include an inert gas such as argon (Ar) gas in addition to the raw material gas.

The diameter of the plurality of through-holes 42a of the upper electrode 42 is less than the diameter of the plurality of gas holes 41b of the dispersion plate 41. While the reactive gas is supplied to the processing space 10s from the gas holes 41b, a dilution gas such as Ar gas or the like is made to flow from the plurality of through-holes 42a to prevent the reactive gas supplied to the processing space 10s from entering the through-holes 42a. The dilution gas at this time functions as a suppression gas for suppressing the inflow of the reactive gas. The dilution gas having the function of a suppression gas may be at least one of Ar gas, N₂ gas, H₂ gas, or O₂ gas.

The controller 80 processes computer-executable instructions that cause the plasma processing apparatus 100 to perform various processes such as film formation by the ALD method. The controller 80 may be configured to control individual components of the plasma processing apparatus 100 to perform various processes. In one embodiment, the controller 80 may be partially or entirely included in the plasma processing apparatus 100. The controller 80 may include a processing part, a storage part, and a communication interface. The controller 80 is realized by, for example, a computer. The processing part may be configured to read a program from the storage part, and execute the read program to perform various control operations. The program may be stored in the storage part in advance, or may be acquired via a medium when necessary. The acquired program is stored in the storage part, and is read from the storage part and executed by the processing part. The medium may be various computer-readable storage media, or may be a communication line connected to the communication interface. The processing part may be a central processing unit (CPU). The storage part may include a random access memory (RAM), a read only memory (ROM), a hard disk drive (HDD), a solid state drive (SSD), or a combination thereof. The communication interface may communicate with the plasma processing apparatus 100 via a communication line such as a local area network (LAN).

The gap (height of the plasma space 10u) between the upper electrode 42 and the dispersion plate 41 and the gap (height of the processing space 10s) between the dispersion plate 41 and the placing table 20 are several millimeters to several tens of millimeters. It is desirable that these spaces are small in order to suppress the deactivation of active species in the gas layer and improve the gas replacement efficiency. As a result, the lower shower plate 41D of the dispersion plate 41 is susceptible to heat input from the plasma and heat from the heater in the placing table 20. The lower shower plate 41D has a plurality of holes, and these holes reduce the solid cross-sectional area that contributes to the horizontal thermal conduction of the lower shower plate 41D, so that the temperature is more likely to increase at the central portion 41D1 of the lower shower plate 41D than at the outer peripheral portion 41D2 thereof. As a result, thermal stress that exceeds the strength of the aluminum alloy, which decreases as the temperature increases, may be generated at the lower shower plate 41D made of an aluminum alloy, and the lower shower plate 41D may be deformed.

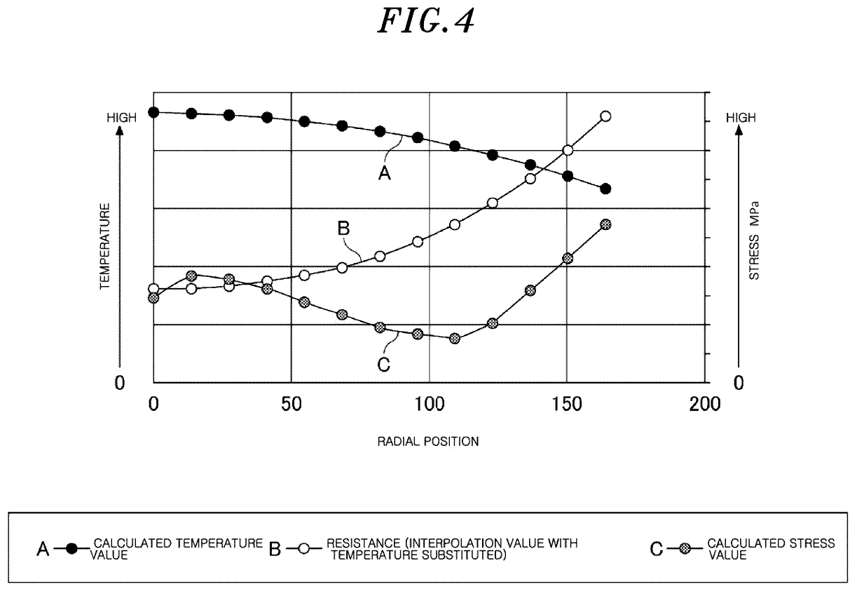

FIG. 4 shows an example of the results of the simulation of thermal stress on the dispersion plate without the slits 46 of FIG. 3. In FIG. 4, the horizontal axis represents the radial position of the disc-shaped dispersion plate, with the center O (see FIG. 3) at 0, the left vertical axis represents the temperature of the dispersion plate, and the right vertical axis represents the stress (thermal stress) applied to the dispersion plate.

Since heat escapes from the central portion toward the outer peripheral portion of the dispersion plate, a line A indicating the temperature (calculated value) of the dispersion plate is high at the central portion and becomes low toward the outer periphery. As a result, a line B indicating the heat resistance of the dispersion plate (interpolation value with temperature substituted) is low at the central portion and becomes high toward the outer peripheral portion. A line C indicating the stress applied to the dispersion plate exceeds the line B indicating the resistance in an area of about 40 mm in the radial direction from the vicinity of 0 mm, which is the center O of the central portion, and the thermal stress exceeding the strength (resistance) of the aluminum alloy of the dispersion plate occurs, which may result in deformation.

### First Embodiment

Therefore, as shown in FIG. 3, the dispersion plate 41 according to the present embodiment has the slits 46 at the central portion 41D1 that penetrates through the lower shower plate 41D in the thickness direction. The slits 46 are formed from the center O of the central portion 41D1 toward the outer peripheral portion 41D2. The slits 46 are formed radially from the center O of the central portion 41D1, and branched into plurality of parts toward the outer peripheral portion 41D2.

In the first embodiment of FIG. 3, six slits 46 are formed radially at equal angles of 60 degrees from the center O of the central portion 41D1. However, the present disclosure is not limited thereto, and more or less than six slits 46 may be formed radially at equal angles. Further, the slits 46 in the first embodiment are branched into two parts at positions extending at equal distances in the radial direction from the center O. As a result, the slits 46 have twelve ends formed at substantially equal intervals in the circumferential direction. However, the number of branching is not limited to one, and may be two or more. Further, the slits 46 are not necessarily branched into two parts, and may be branched into three or more parts. The number of slits 46 toward the outer peripheral portion 41D2 may be increased in a stepwise manner.

The slits 46 are formed rotationally symmetrical with respect to an axis passing through the center O of the central portion 41D1. The symmetry in which objects overlap each other when they are rotated 360/n degrees is referred to as “n-fold symmetry.” The slit 46 of the first embodiment in FIG. 3 is 6-fold symmetric, and is a gap that substantially overlaps when rotated 60 degrees.

The slits 46 of the first embodiment penetrate through the lower shower plate 41D in the thickness direction across the gas holes 41b to connect the gas holes 41b formed in the central portion 41D1. The slits 46 of the first embodiment are formed to connect the centers of the gas holes 41b. The slits 46 that connect the gas holes 41b have the same width. The slits 46 of the first embodiment are formed to connect the gas holes 41b to thereby form two sides of a triangle after branching. However, the shape formed by the slit 46 after branching is not limited to a triangle.

By forming the slits 46 in the lower shower plate 41D, the stress caused by the difference in expansion between the central portion 41D1 of which temperature is likely to increase and the outer peripheral portion 41D2 of which temperature is likely to decrease is less likely to occur depending on the temperature distribution of the dispersion plate 41. Accordingly, the stress generated at the lower shower plate 41D when the lower shower plate 41D receives heat from a heater or plasma can be alleviated, thereby reducing the thermal stress of the dispersion plate 41. Hence, it is possible to suppress the deformation of the dispersion plate 41 in the vertical direction. Further, as the temperature increases, the dispersion plate 41 expands in a direction in which the slits 46 become narrower. Therefore, in the actual environment, the gap of the slits 46 becomes narrower, and the influence of the slits 46, such as the distribution of the reactive gas supplied from the plasma space 10u to the processing space 10s, can be reduced.

In particular, the slits 46 in the first embodiment are gaps extending from the center O of the central portion 41D1 toward the outer peripheral portion 41D2, and are formed radially from the center O. Therefore, the slits 46 do not prevent heat from being transferred from the center O of the lower shower plate 41D to the outer peripheral portion 41D2, and the temperature distribution of the lower shower plate 41D does not change regardless of the existence/non-existence of the slits 46. Accordingly, the stress generated by the temperature distribution of the lower shower plate 41D does not change regardless of the existence/non-existence of the slits 46. Hence, the width of the slits 46 changes depending on the expansion and contraction of the lower shower plate 41D due to the heat input, and the stress generated at the lower shower plate 41D can be alleviated. As a result, the vertical deformation of the dispersion plate 41 can be suppressed.

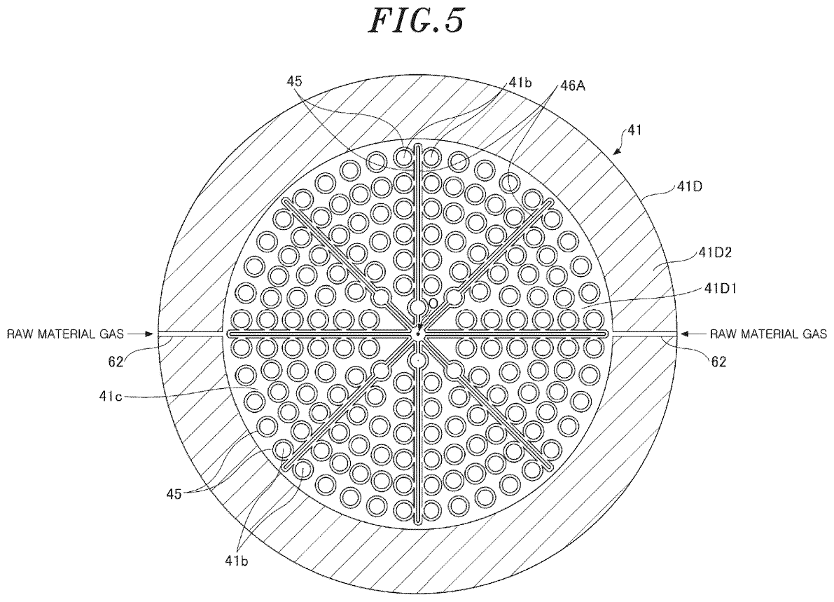

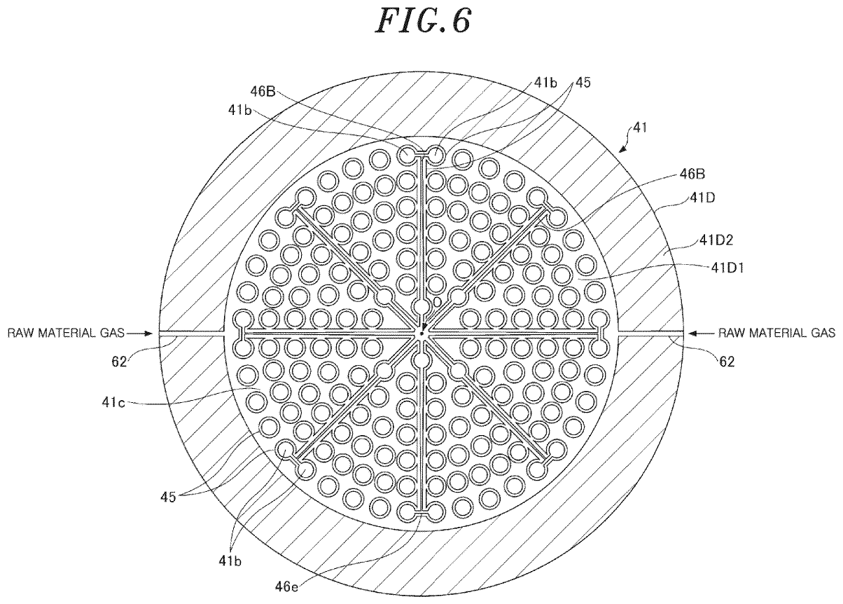

The state in which the lower shower plate 41D expands and contracts due to the heat input from the plasma or the heat of the heater may be measured, and the width of the slits 46 may be determined depending on the degree of expansion. Next, the slits 46A of the second embodiment, which have the same slit width, and the slits 46B of the third embodiment, which have different slit widths, will be described with reference to FIGS. 5 and 6. FIG. 5 is an example of a cross-sectional view taken along line A-A in FIG. 2, and shows the slits 46A of the second embodiment. FIG. 6 is an example of a cross-sectional view taken along line A-A in FIG. 2, and shows the slits 46B of the third embodiment.

### Second Embodiment

The slits 46A of the second embodiment in FIG. 5 are gaps penetrating through the lower shower plate 41D, and are formed radially from the center O of the central portion 41D1 toward the outer peripheral portion 41D2. The slits 46A of the second embodiment are 8-fold symmetrical, and overlap when rotated 45 degrees. The slits 46A of the second embodiment have a portion penetrating through the lower shower plate 41D while avoiding the gas holes 41b, and a portion penetrating through the lower shower plate 41D across the gas holes 41b. The slits 46A of the second embodiment have the same width.

### Third Embodiment

The slits 46B of the third embodiment in FIG. 6 are gaps penetrating through the lower shower plate 41D, and are formed radially from the center O of the central portion 41D1 toward the outer peripheral portion 41D2. The slits 46B of the second embodiment are 8-fold symmetric and overlap when rotated 45 degrees. The slits 46B of the third embodiment have a portion penetrating through the lower shower plate 41D while avoiding the plurality of gas holes 41b and a portion penetrating through the lower shower plate 41D across the plurality of gas holes 41b.

The slits 46B of the third embodiment have a width that varies along their length. The width of the slits 46B becomes gradually smaller from the center O of the central portion 41D1 toward the outer peripheral portion 41D2. In other words, in the third embodiment, the central portion 41D1 receives more heat than the outer peripheral portion 41D2, so that the width of the slits 46B is large at the central portion 41D1 and is small at the outer peripheral portion 41D2.

In this manner, the width of the slits 46B may be designed in consideration of the amount of expansion of the lower shower plate 41D. Accordingly, the slits 46B can be closed or narrowed depending on the amount of expansion of the lower shower plate 41D due to the heat input from the plasma or heater during the substrate processing. Hence, a gas with a desired conductance can be supplied from the plurality of gas holes 41b in a state where the stress generated at the lower shower plate 41D is alleviated by substantially closing the slits 46B during the substrate processing.

The end of the slit 46B is preferably connected to at least one of the plurality of gas holes 41b. Stress is likely to concentrate at the end 46e of the slit 46B. Therefore, in the third embodiment, the end 46e of each of the eight slits 46B is connected to two gas holes 41b located on the outermost periphery of the central portion 41D1. Accordingly, it is possible to avoid stress concentration at the end 46e of the slits 46B.

Further, the slit preferably has at least one of a portion penetrating through the lower shower plate 41D across the gas holes 41b or a portion penetrating through the lower shower plate 41D while avoiding the gas holes 41b.

### Fourth Embodiment

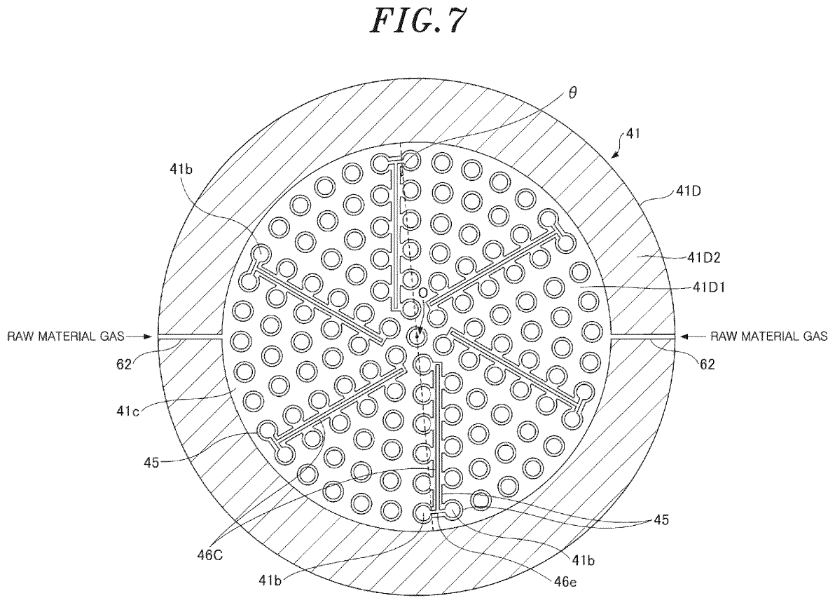

FIG. 7 is an example of a cross-sectional view taken along line A-A in FIG. 2, showing slits 46C of the fourth embodiment. The slits 46C of the fourth embodiment are inclined at an angle θ from a radial line (indicated by a dashed line in FIG. 7) passing through the center O. In other words, the slits 46C of the fourth embodiment are gaps penetrating through the lower shower plate 41D, and are formed radially toward the outer peripheral portion 41D2 while being inclined at an angle θ from the radial line passing through the center O of the central portion 41D1. The slits 46C of the fourth embodiment are 6-fold symmetric, and overlap when rotated 60 degrees. The slits 46C of the fourth embodiment penetrate through the lower shower plate 41D in the thickness direction while avoiding the plurality of gas holes 41b.

The ends 46e of the six slits 46C are connected to two gas holes 41b located on the outermost periphery of the central portion 41D1. Accordingly, it is possible to prevent stress from concentrating at the ends 46e of the slits 46C.

In order to prevent stress from concentrating at the ends of the slits, R of the ends of the slits may be designed to be about 5 to 6 mm.

### Fifth Embodiment

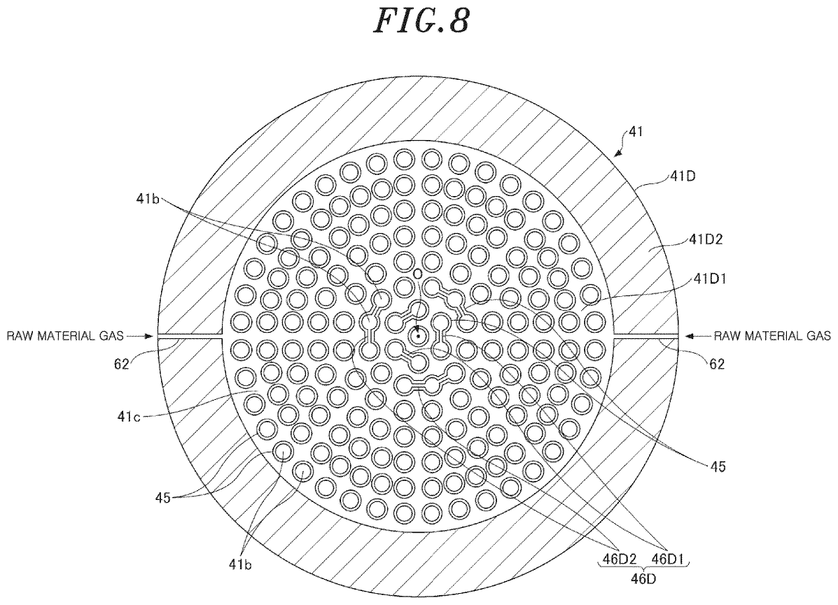

FIG. 8 is an example of a cross-sectional view taken along line A-A in FIG. 2, showing slits 46D of a fifth embodiment. The slits 46D of the fifth embodiment are gaps that are formed to connect the gas holes 41b adjacent in the circumferential direction and penetrate through the lower shower plate 41D. In the slit 46D of the fifth embodiment, slits 46D1 that connect six gas holes 41b arranged in the circumferential direction in three groups at positions closest to the center O of the central portion 41D1 are formed in the circumferential direction. In addition, slits 46D2 that connects nine gas holes 41b in three groups among twelve gas holes 41b arranged in the circumferential direction at positions next closest to the center O of the central portion 41D1 are formed in the circumferential direction. The slits 46D2 may connect the twelve gas holes 41b in three groups. The slits 46D1 and 46D2 are formed concentrically. In order to reduce the influence of the slits 46D1 and 46D2 on the heat conduction from the center O to the outer peripheral portion 41D2 of the lower shower plate 41D, the slits 46D1 are not formed in some of the adjacent gas holes 41b among the gas holes 41b arranged in the circumferential direction. Similarly, the slits 46D2 are not formed in some of the adjacent gas holes 41b among the gas holes 41b arranged in the circumferential direction. For example, in the example of FIG. 8, the slits 46D1 do not connect every other gas holes 41b adjacent in the circumferential direction. However, the arrangement of the slits 46D1 and 46D2 is not limited to the example shown in FIG. 8. In the fifth embodiment, the slits 46D1 and 46D2 are formed rotationally symmetrically with respect to the axis passing through the center O. In the example of FIG. 8, the slits 46D1 and 46D2 are 3-fold symmetric, and are gaps substantially overlap when rotated 120 degrees.

Although not shown in FIG. 8, in the area of the central portion 41D1, other slits 46D may be formed outside the slits 46D1 and 46D2 in a concentric manner with respect to the center O of the central portion 41D1. Accordingly, the stress of the lower shower plate 41D can be alleviated, thereby reducing the thermal stress of the dispersion plate 41. Hence, the deformation of the dispersion plate 41 in the vertical direction can be suppressed.

### Other Applications

As shown in FIGS. 3 and 5 to 8, the lower shower plate 41D has the central portion 41D1 and the outer peripheral portion 41D2 surrounding the central portion 41D1. The plurality of holes or slits are provided in the central portion 41D1, and are not provided in the outer peripheral portion 41D2. In other words, the outer peripheral portion 41D2 is annular, and is formed continuously with the outer periphery of the central portion 41D1 having the slits 46, 46A to 46D penetrating through the lower shower plate 41D in the thickness direction. The outer peripheral portion 41D2 is integrated with the central portion 41D1 to form the dispersion plate 41.

The ratio of the radius of the central portion 41D1 to the radial width of the outer peripheral portion 41D2 is 1:0.05 to 1:0.5. By designing the area of the outer peripheral portion 41D2 to be wider than the central portion 41D1, the temperature distribution from the central portion 41D1 to the outer peripheral portion 41D2 becomes gentle. As a result, the slits 46, 46A to 46D can efficiently alleviate the stress of the lower shower plate 41D and reduce the thermal stress of the dispersion plate 41.

Although the example in which the slits 46 are provided in the dispersion plate 41 has been described, the present disclosure is not limited thereto. At least one of the dispersion plate 41 or the upper electrode 42 in FIG. 1 may have the slits 46. Further, the shower head 30 in FIG. 1 may not have the upper electrode 42.

The slits 46 and the channel 41c are separated by the partition wall 45. Accordingly, the slits 46 do not affect the supply of the raw material gas.

As described above, by providing the slits in the dispersion plate 41, the stress, which is caused by the difference in expansion between the central portion 41D1 of the dispersion plate 41 where the temperature is likely to increase and the outer peripheral portion 41D2 of the dispersion plate 41 where the temperature is likely to decrease, is less likely to be generated. In addition, since the dispersion plate 41 expands in a direction in which the slits become narrower, the gap of the slits becomes narrow in the actual environment, which makes it possible to reduce the influence of the slit itself. Accordingly, it is not required to increase the distance between the placing table 20 and the dispersion plate 41 in order to prevent the dispersion plate 41 from being plastically deformed by the stress caused by a decrease in the strength of the lower shower plate 41D due to an increase in the temperature. Further, in order to avoid plastic deformation of the dispersion plate 41, it is possible to eliminate restrictions such as limits on the increase of the processing temperature during the substrate processing or the increase of the high-frequency power for plasma generation. Accordingly, the effects of the plasma uniformity control and the ion flux control by providing the dispersion plate 41 can be expected without restricting the effect of reducing the capacity of the substrate processing apparatus for improving productivity, and the effect of increasing the deposition speed by using VHF or UHF and by increasing the input power.

The dispersion plate, the gas supply mechanism, and the substrate processing apparatus according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

In the above embodiments, the dispersion plate 41 having a plurality of holes functioning as gas supply holes has the slits 46, 46A to 46D. However, the present disclosure is not limited thereto. For example, the slits 46, 46A to 46D can be applied to an intermediate electrode, a ground electrode, an ion cut filter, or an ion trap that has a plurality of holes and is intended to control plasma produced between the slits and the upper electrode. Further, they may be applied to a heat shield plate, a shielding plate, an absorbing plate, a reflecting plate, or the like that has a plurality of holes and is intended to control heat or light.

This application claims priority to Japanese Patent Application No. 2023-010473 filed on Jan. 26, 2023, the entire contents of which are incorporated herein by reference.

1. A dispersion plate located in a processing chamber of a substrate processing apparatus, comprising:
a disc-shaped main body having a central portion and an outer peripheral portion surrounding the central portion; and
a plurality of first holes formed in the central portion and opened into a first space in the processing chamber for processing a substrate,
wherein the main body has at the central portion slits penetrating through the main body in a thickness direction.

2. The dispersion plate of claim 1, wherein the slits are formed toward the outer peripheral portion at a predetermined angle from the center of the central portion or from a radial line passing through the center.

3. The dispersion plate of claim 2, wherein the slits are formed radially from the center of the central portion or at a predetermined angle from the center.

4. The dispersion plate of claim 3, wherein the slits are branched into a plurality of parts toward the outer peripheral portion.

5. The dispersion plate of claim 1, wherein the slits are formed in a circumferential direction.

6. The dispersion plate of claim 1, wherein the slits are formed rotationally symmetrically with respect to an axis passing through the center of the central portion.

7. The dispersion plate of claim 1, wherein the slits penetrate through the main body in the thickness direction across at least some of the plurality of first holes.

8. The dispersion plate of claim 1, wherein the slits penetrate through the main body in the thickness direction while avoiding the first holes.

9. The dispersion plate of claim 7, wherein the slits are formed to connect the centers of at least some of the plurality of first holes.

10. The dispersion plate of claim 1, wherein the ends of the slits are connected to at least one of the plurality of first holes.

11. The dispersion plate of claim 1, wherein each of the slits has the same width along its length.

12. The dispersion plate of claim 1, wherein each of the slits has a width that varies along its length.

13. The dispersion plate of claim 12, wherein the width of each of the slits becomes smaller from the center of the central portion toward the outer peripheral portion.

14. The dispersion plate of claim 1, wherein the plurality of first holes supply a first gas to the first space, and
the main body has:
a diffusion path that is formed in the central portion to diffuse a second gas different from the first gas; and
a plurality of second holes through which the second gas flows from the diffusion path toward the first space.

15. A gas supply mechanism including the dispersion plate described in claim 1.

16. A substrate processing apparatus comprising:
a gas supply mechanism having the dispersion plate described in claim 1; and
a placing table located to face the dispersion plate, wherein a substrate placed on the placing table is processed by a gas supplied from the gas supply mechanism.
